(19) United States
(12) Patent Application Publication
(10) Pub. No.: US 2021/0184706 A1
(43) Pub. Date: Jun. 17, 2021

(54) FILTER DEVICE, AND RADIO-FREQUENCY FRONT-END CIRCUIT AND COMMUNICATION APPARATUS USING THE SAME

(71) Applicant: Murata Manufacturing Co., Ltd., Kyoto (JP)

(72) Inventors: Taizo HISANO, Kyoto (JP); Hirotsugu MORI, Kyoto (JP)

(21) Appl. No.: 17/186,143

(22) Filed: Feb. 26, 2021

Related U.S. Application Data
(63) Continuation of application No. PCT/JP2019/031348, filed on Aug. 8, 2019.

(30) Foreign Application Priority Data
Sep. 19, 2018 (JP) 2018-174451

(51) Int. Cl. H04B 1/00; H04L 27/00

(52) U.S. Cl. CPC H04B 1/006; H04L 27/0002

(57) ABSTRACT

A filter device (100) includes a flat-shaped insulator (20), a filter (FLT1) that is disposed at the insulator (20) and is configured to pass a radio-frequency signal and a switching circuit (SWIC) configured to change at least one of a pass band and an attenuation band of the filter (FLT1). A control line (62 or 63) configured to supply driving power or a control signal to the switching circuit (SWIC) is formed at the insulator (20). The control line (62 or 63) is disposed so as not to overlap a radio-frequency line that passes a radio-frequency signal in the filter (FLT1) when the insulator (20) is viewed in plan.

### CROSS REFERENCE TO RELATED APPLICATION

This is a continuation of International Application No. PCT/JP2019/031348 filed on Aug. 8, 2019 which claims priority from Japanese Patent Application No. 2018-174451 filed on Sep. 19, 2018. The contents of these applications are incorporated herein by reference in their entireties.

### BACKGROUND OF THE DISCLOSURE

### Field of the Disclosure

The present disclosure relates to a filter device, and a radio-frequency front-end circuit and a communication apparatus using the filter device (hereinafter also referred to as “a filter device or the like”), and, more particularly, to a technique for suppressing the occurrence of an unnecessary wave in a filter device or the like used in a radio-frequency circuit.

### Description of the Related Art

Japanese Unexamined Patent Application Publication No. 6-215985 (Patent Document 1) discloses a multilayer LC filter formed at a dielectric substrate having a multilayer structure.

Patent Document 1: Japanese Unexamined Patent Application Publication No. 6-215985

### BRIEF SUMMARY OF THE DISCLOSURE

There are cases where a communication apparatus uses a variable frequency filter (hereinafter also referred to as a “tunable filter”) which has a switching circuit and other components mounted on a substrate of a multilayer filter device to make the attenuation pole or frequency band of the filter variable.

A switching circuit typically includes a nonlinear element in which an applied voltage and a current are not proportional to each other. It is known that when a radio-frequency signal passes through such a nonlinear element, the signal is distorted and a harmonic is generated. When the harmonic generated by the nonlinear element is coupled to a radio-frequency line for transmitting a radio-frequency signal in a filter, an unnecessary wave, typified by harmonic distortion, intermodulation distortion, or cross modulation distortion, is generated in a radio-frequency signal passing through the filter and may lead to the degradation of the filter characteristics.

The present disclosure has been made to solve the above problem and it is an object of the present disclosure to suppress the generation of an unnecessary wave by a nonlinear element in a tunable filter formed at a multilayer substrate to suppress the degradation of the filter characteristics.

A filter device according to an aspect of the present disclosure includes a flat-shaped insulator, a filter that is disposed at the insulator and is configured to pass a radio-frequency signal in a first frequency band, and a switching circuit configured to change at least one of a pass band and an attenuation band of the filter. A control line configured to supply driving power or a control signal to the switching circuit is formed at the insulator. The control line is disposed so as not to overlap a radio-frequency line that passes a radio-frequency signal in the filter when the insulator is viewed in plan.

A filter device according to another aspect of the present disclosure includes a dielectric substrate having a multilayer structure, a filter that is disposed at the dielectric substrate and is configured to pass a radio-frequency signal in a first frequency band, and a switching circuit configured to change at least one of a pass band and an attenuation band of the filter. A control line configured to supply driving power or a control signal to the switching circuit is formed at the dielectric substrate. The control line overlaps at least a part of a radio-frequency line that passes a radio-frequency signal in the filter when the dielectric substrate is viewed in plan. In a portion in which the control line and the radio-frequency line overlap, a ground electrode is disposed between the control line and the radio-frequency line.

A filter device according to still another aspect of the present disclosure includes a dielectric substrate, a first filter that is disposed at the dielectric substrate and is configured to pass a radio-frequency signal in a first frequency band, a second filter configured to pass a radio-frequency signal in a second frequency band different from the first frequency band, and a switching circuit configured to switch between the first filter and the second filter. A control line configured to supply driving power or a control signal to the switching circuit is formed at the dielectric substrate. The control line is disposed so as not to overlap a radio-frequency line that passes a radio-frequency signal in each of the first filter and the second filter when the dielectric substrate is viewed in plan.

In a filter device according to the present disclosure, a control line for a switching circuit is disposed so as not to face a radio-frequency line that passes a radio-frequency signal when an insulator (a dielectric substrate) is viewed in plan. Accordingly, the electromagnetic coupling between the radio-frequency line and the control line is suppressed. The generation of an unnecessary wave by a nonlinear element included in the switching circuit can therefore be prevented. This can lead to the suppression of the degradation of the filter characteristics.

### BRIEF DESCRIPTION OF THE SEVERAL VIEWS OF THE DRAWINGS

FIG. 1 is a block diagram of a communication apparatus including a radio-frequency front-end circuit including a multiplexer to which a filter device according to a first embodiment is applied.

FIG. 2 is a circuit diagram illustrating in detail the multiplexer in FIG. 1.

FIG. 3 is a diagram describing the principle that an unnecessary wave is generated under the influence of a nonlinear element.

FIG. 4 is a plan view of the multiplexer in FIG. 2.

FIG. 5 is a partial cross-sectional view of the multiplexer when the multiplexer is viewed from the direction of the arrows of line V-V in FIG. 4.

FIG. 6 is a perspective view of the multiplexer in FIG. 2.

Each of FIGS. 7A and 7B is a diagram describing the influence of a harmonic on a high-pass filter.

Each of FIGS. 8A and 8B is a diagram describing the influence of a harmonic on a low-pass filter.

FIG. 9 is a plan view of a multiplexer to which a filter device according to a second embodiment is applied.

FIG. 10 is a cross-sectional view of the multiplexer along a control wiring line in FIG. 9.

FIG. 11 is a circuit diagram of a multiplexer to which a filter device according to a third embodiment is applied.

FIG. 12 is a circuit diagram of a multiplexer to which a filter device according to a fourth embodiment is applied.

### DETAILED DESCRIPTION OF THE DISCLOSURE

Embodiments of the present disclosure will be described in detail below with reference to the accompanying drawings. In the drawings, the same reference numeral is used to represent the same part or the corresponding part to avoid repeated explanation.

### First Embodiment

(Configuration of Radio-Frequency Front-End Circuit)

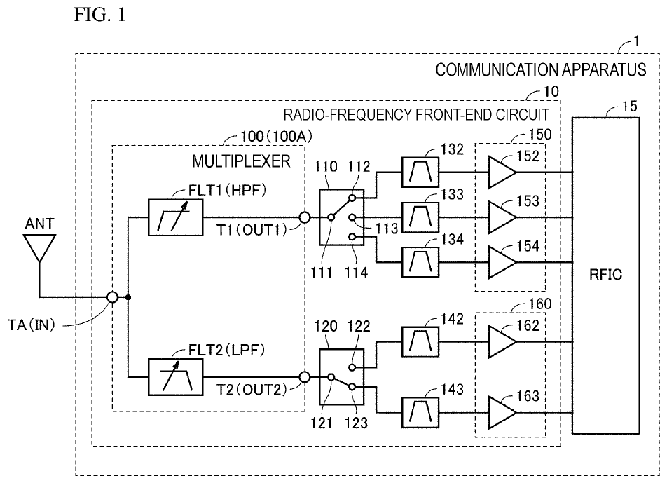

FIG. 1 is a block diagram of a communication apparatus 1 including a radio-frequency front-end circuit 10 including a multiplexer 100 to which a filter device according to the first embodiment is applied. The radio-frequency front-end circuit 10 separates the radio-frequency signals received by an antenna device ANT into a plurality of frequency bands determined in advance and transmits them to a processing circuit (not illustrated). The radio-frequency front-end circuit 10 is used in a communication apparatus, such as a portable terminal (e.g., a cellular phone, a smartphone, or a tablet) or a personal computer having a communication function.

Referring to FIG. 1, the communication apparatus 1 includes the radio-frequency front-end circuit 10 and an RF signal processing circuit (hereinafter also referred to as an “RFIC”) 15. The radio-frequency front-end circuit 10 is a reception front-end circuit. The radio-frequency front-end circuit 10 includes the multiplexer 100, switches 110 and 120, filters 132 to 134, 142, and 143 and amplification circuits 150 and 160. The amplification circuit 150 includes amplifiers 152 to 154. The amplification circuit 160 includes amplifiers 162 and 163.

The multiplexer 100 is a duplexer including filters FLT1 and FLT2 that have different frequency ranges as respective pass bands.

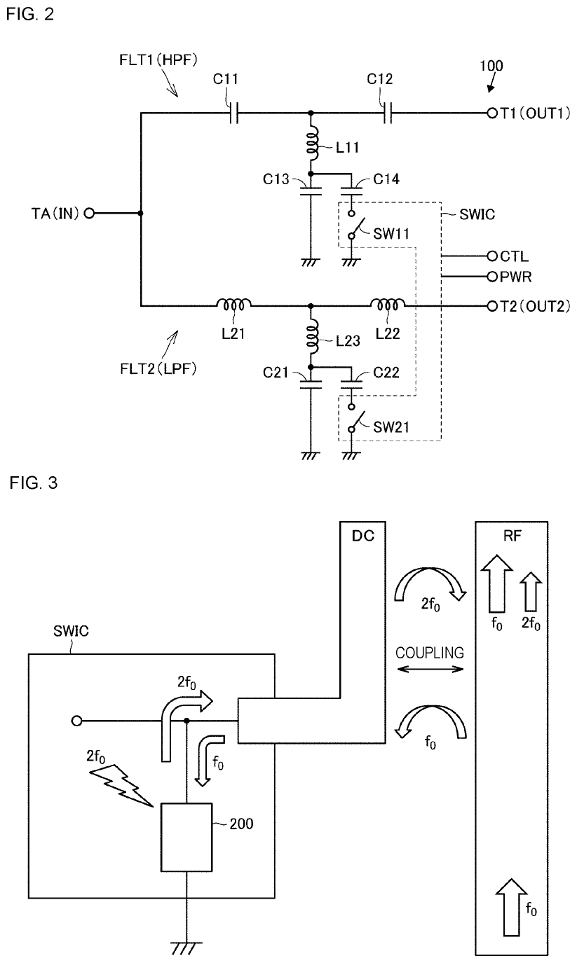

The filter FLT1 is connected between an antenna terminal TA and a first terminal T1. The filter FLT1 is a high-pass filter (HPF) that has a frequency range in the high band group as a pass band and a frequency range in the low band group as an attenuation band. As described below, the filter FLT1 is a tunable filter including a variable frequency circuit including a switch SW11 (FIG. 2). The filter FLT1 can change at least one of the pass band and attenuation band thereof by switching between the conductive state and non-conduction state of the switch SW11.

The filter FLT2 is connected between the antenna terminal TA and a second terminal T2. The filter FLT2 is a low-pass filter (LPF) that has a frequency range in the low band group as a pass band and a frequency range in the high band group as an attenuation band. The filter FLT2 is a tunable filter including a variable frequency circuit including a switch SW21 (FIG. 2). The filter FLT2 can change at least one of the pass band and attenuation band thereof by switching between the conductive state and non-conduction state of the switch SW21.

Each of the filters FLT1 and FLT2 passes only a radio-frequency signal in the pass band thereof among the radio-frequency signals received by the antenna device ANT to separate the reception signals from the antenna device ANT into signals in a plurality of frequency bands determined in advance.

The switch 110 is connected between the multiplexer 100 and the band-pass filters (BPFs) 132 to 134. The switch 120 is connected between the multiplexer 100 and the BPFs 142 and 143. The switch 110 connects a signal path for the high band group to the BPFs 132 to 134 in accordance with a control signal from a control unit (not illustrated). The switch 120 connects a signal path for the low band group to the BPFs 142 and 143 in accordance with a control signal from the control unit.

Specifically, the switch 110 has a common terminal 111 connected to the first terminal T1 of the filter FLT1 and selection terminals 112 to 114 connected to the BPFs 132 to 134, respectively. The switch 120 has a common terminal 121 connected to the second terminal T2 of the filter FLT2 and selection terminals 122 and 123 connected to the BPFs 142 and 143, respectively.

The BPFs 132 to 134 are connected to the amplifiers 152 to 154 in the amplification circuit 150, respectively. The BPFs 142 and 143 are connected to the amplifiers 162 and 163 in the amplification circuit 160, respectively. Each of the amplifiers 152 to 154, 162, and 163 is, for example, a low-noise amplifier formed of a transistor and other components. Each of the amplifiers amplifies a radio-frequency signal, which has been received by the antenna device ANT and passed through the corresponding BPF, with a low noise and transmits it to the RFIC 15.

The RFIC 15 is an RF signal processing circuit for processing a radio-frequency signal transmitted from or received by the antenna device ANT. Specifically, the RFIC 15 performs signal processing such as downconversion upon a radio-frequency signal inputted from the antenna device ANT via a reception-side signal path in the radio-frequency front-end circuit 10 and outputs a reception signal obtained as a result of the signal processing to a baseband signal processing circuit (not illustrated).

Each of the amplification circuits 150 and 160 may be formed of a single amplifier. In that case, a switch is provided between the amplification circuit 150 and the BPFs 132 to 134 and a switch is provided between the amplification circuit 160 and the BPFs 142 and 143.

In the radio-frequency front-end circuit 10 exemplarily illustrated in FIG. 1, the pass bands of the BPFs 132 to 134 are included in the frequency band of the filter FLT1, and the pass bands of the filters 142 and 143 are included in the frequency band of the filter FLT2.

In the case where the radio-frequency front-end circuit 10 is used as a reception circuit as illustrated in FIG. 1, the antenna terminal TA becomes an input terminal IN, and the first terminal and the second terminal become a first output terminal OUT1 and a second output terminal OUT2, respectively in the multiplexer 100.

The radio-frequency front-end circuit may be used as a transmission circuit. In that case, the first terminal and the second terminal become input terminals, and the antenna terminal TA becomes a common output terminal in the multiplexer 100. The amplifier included in the amplification circuit becomes a power amplifier.

(Circuit Configuration of Multiplexer)

FIG. 2 is a diagram illustrating the detailed circuit configuration of the multiplexer 100 in FIG. 1. As illustrated in FIG. 1, the filter FLT1 is connected between the antenna terminal TA and the first terminal T1. The filter FLT2 is connected between the antenna terminal TA and the second terminal T2.

The filter FLT1 includes capacitors C11 and C12 forming a series arm circuit and capacitors C13 and C14, an inductor L11, and the switch SW11 forming a parallel arm circuit. The capacitors C11 and C12 are connected in series between the antenna terminal TA and the first terminal T1. One end of the inductor L11 is connected to a connection node between the capacitors C11 and C12. The capacitor C13 is connected between the other end of the inductor L11 and a ground potential. One end of the capacitor C14 is also connected to the other end of the inductor L11, and the other end of the capacitor C14 is connected to the ground potential via the switch SW11.

The switch SW11 is switched between the conductive state and the non-conductive state in accordance with a control signal from a control unit (not illustrated). By switching between the states of the switch SW11, the resonant frequency of the parallel arm circuit can be changed and the frequency at an attenuation pole formed in the parallel arm circuit can be adjusted. As a result, at least one of the pass band and attenuation band of the filter FLT1 can be variable.

The filter FLT2 includes inductors L21 and L22 forming a series arm circuit and an inductor L23, capacitors C21 and C22, and the switch SW21 forming a parallel arm circuit. The inductors L21 and L22 are connected in series between the antenna terminal TA and the second terminal T2. One end of the inductor L23 is connected to a connection node between the inductors L21 and L22. The capacitor C21 is connected between the other end of the inductor L23 and the ground potential. One end of the capacitor C22 is also connected to the other end of the inductor L23, and the other end of the capacitor C22 is connected to the ground potential via the switch SW21.

Also, in the filter FLT2, by switching between the states of the switch SW21, the resonant frequency of the parallel arm circuit can be changed and the frequency at an attenuation pole formed in the parallel arm circuit can be adjusted.

Each of the switch SW11 in the filter FLT1 and the switch SW21 in the filter FLT2 is, for example, a transistor and is formed in a switching circuit SWIC. Driving power is supplied to the switching circuit SWIC via a power terminal PWR. A control signal for operating the switches SW11 and SW21 is transmitted to the switching circuit SWIC from an external control device (not illustrated) via a control terminal CTL.

Thus, in the multiplexer 100 illustrated in FIG. 2, there is provided the switching circuit SWIC for changing at least one of the pass band and attenuation band of each of the filters FLT1 and FLT2 that are tunable filters. In the switching circuit SWIC having such a configuration, there is provided a control circuit for operating a switch in response to an externally transmitted instruction. This control circuit includes a nonlinear element in which an applied voltage and a flowing current are in a nonlinear relationship.

When a radio-frequency signal passes through such a nonlinear element, the signal is distorted and an unnecessary wave, typified by harmonic distortion, intermodulation distortion, or cross modulation distortion, is generated and may lead to the degradation of the filter characteristics.

Accordingly, in a filter device according to the first embodiment including tunable filters, a radio-frequency line that passes a radio-frequency signal and a control line that transmits driving power or a control signal to the switching circuit SWIC are disposed so as not to overlap each other when the dielectric substrate is viewed in plan. Such disposition suppresses the electromagnetic coupling between the radio-frequency line and the control line and suppresses the generation of an unnecessary wave in the radio-frequency line. The degradation of the filter characteristics can therefore be suppressed.

(Principle of Generation of Unnecessary Wave)

FIG. 3 is a diagram schematically illustrating the principle that an unnecessary wave is generated in a radio-frequency line under the influence of a nonlinear element. The case will be described with reference to FIG. 3 where an unnecessary wave exemplarily represents harmonic distortion.

Referring to FIG. 3, a control line for transmitting driving power or a control signal to the switching circuit SWIC is represented by DC, and a radio-frequency line for passing a radio-frequency signal is represented by RF. The switching circuit SWIC includes a nonlinear element 200 that is, for example, an electrostatic discharge (ESD) protection circuit. Power or a signal that passes through the control line is of direct current or of alternating current of approximately several hundred KHz. The frequency of alternating current passing through the control line is lower than that of a radio-frequency signal on the order of MHz or GHz passing through the radio-frequency line.

In this embodiment, the terms “the radio-frequency line RF” and “the control line DC” do not necessarily mean only wiring lines and also mean elements and circuits through which a target signal passes.

It is assumed that the frequency of a radio-frequency signal passing through the radio-frequency line RF is f0. At that time, around the radio-frequency line RF, an electromagnetic field of the frequency f0 is formed by the passing radio-frequency signal. In the case where the radio-frequency line RF and the control line DC are disposed to face each other, the radio-frequency line RF and the control line DC are electromagnetically coupled to each other by the generated electromagnetic field. The radio-frequency component of the frequency f0 is therefore superimposed on power or a signal passing through the control line DC.

The radio-frequency component superimposed on the control line DC is transmitted to the nonlinear element 200 included in the switching circuit SWIC, and the nonlinear element 200 causes harmonic distortion at a multiple. Referring to FIG. 3, the frequency of the harmonic that has occurred is twice (2f0) the frequency of a harmonic signal.

The harmonic that has occurred in the nonlinear element 200 is transmitted through the control line DC. In a portion where the radio-frequency line RF and the control line DC face each other, the harmonic of the frequency 2f0 superimposed on the control line DC is transmitted to the side of the radio-frequency line RF under the influence of the electromagnetic coupling between the radio-frequency line RF and the control line DC. As a result, the harmonic component of the frequency 2f0 generated by the nonlinear element 200 appears in a signal passing through the radio-frequency line RF.

In the above example, the case has been described where a radio-frequency signal of a single frequency is inputted into the radio-frequency line. In the case where two or more radio-frequency signal are inputted into the radio-frequency line, the two radio-frequency signals cause intermodulation distortion or cross modulation distortion in the nonlinear element 200 like in the above case.

Thus, an unnecessary wave arising from a nonlinear element is generated under the influence of the electromagnetic coupling between the radio-frequency line RF and the control line DC. Accordingly, by disposing the radio-frequency line RF and the control line DC such that they do not face each other for the avoidance of the coupling between the radio-frequency line RF and the control line DC in a multiplexer, the generation of an unnecessary wave in the radio-frequency line RF can be suppressed.

(Arrangement of Elements in Multiplexer)

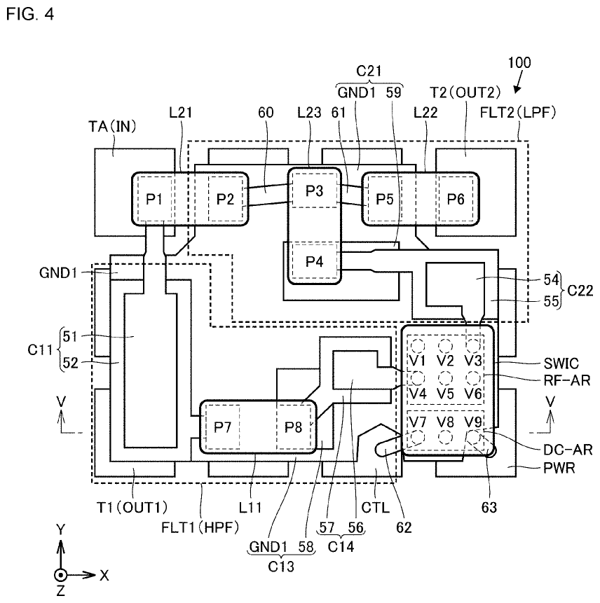

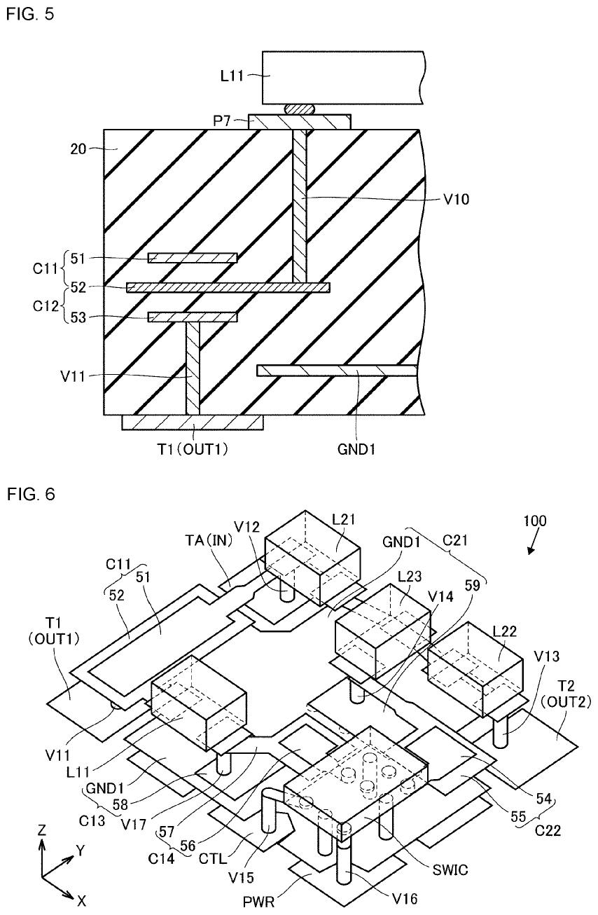

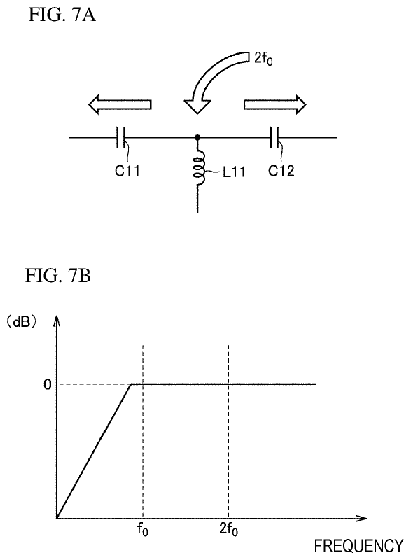

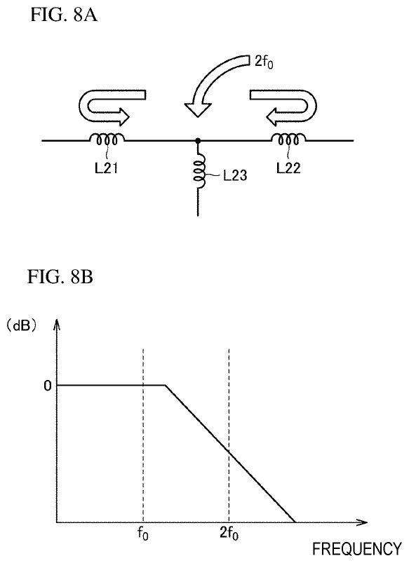

Next, the detailed configuration of the multiplexer 100 will be described with reference to FIGS. 4 to 6. FIG. 4 is a plan view of the multiplexer 100 in FIG. 2 when the multiplexer 100 is viewed from the direction of the normal line of a dielectric substrate 20 (the Z-axis direction in FIG. 4) made of an insulating material. FIG. 6 is a perspective view of the multiplexer 100. FIG. 5 is a partial cross-sectional view of the multiplexer 100 when the multiplexer 100 is viewed from the direction of the arrows of line V-V in FIG. 4.

For ease of explanation, a dielectric portion is not illustrated and internal elements such as wiring patterns are illustrated in the state where they are visible in the dielectric substrate 20 in FIGS. 4 and 6. In a portion where a plurality of elements overlap, a part of a hidden part is represented by a broken line. For the sake of convenience, a negative direction of the Z axis in FIG. 4 will be referred to as an undersurface side of the dielectric substrate 20, and the positive direction of the Z axis will be referred to as an upper surface side of the dielectric substrate 20 in the following description.

Referring to FIGS. 4 and 6, a plurality of terminal electrodes are spaced apart from each other along the periphery of the undermost surface of the dielectric substrate 20. In the top-left corner in FIG. 4, the antenna terminal TA is disposed. In the bottom-left corner in FIG. 4, the first terminal T1 connected to the high-pass filter FLT1 is disposed. In the top-right corner in FIG. 4, the second terminal T2 connected to the low-pass filter FLT2 is disposed.

In the bottom-right corner in FIG. 4, the power terminal PWR for receiving power for the switching circuit SWIC is disposed. At a position adjacent to the power terminal PWR in the X-axis direction, the control terminal CTL for receiving a control signal is disposed.

In a large area in a layer spaced apart from the terminal electrodes in the upper-surface direction (the positive direction of the Z axis), a ground electrode GND1 is formed.

First, the configuration of the high-pass filter FLT1 will be described. The antenna terminal TA is connected to an electrode pad P1 on the upper surface side via a via V12. An electrode 51 extending in the negative direction of the Y axis in FIG. 4 is connected to the via V12. An electrode 52 is disposed apart from the electrode 51 on the undersurface side (the negative direction of the Z axis). The electrodes 51 and 52 form the capacitor C11 in FIG. 2.

As illustrated in the cross-sectional view in FIG. 5, an electrode 53, which overlaps the electrode 52 and is therefore invisible in FIGS. 4 and 6, is disposed on the undersurface side of the electrode 52. The electrodes 52 and 53 form the capacitor C12 in FIG. 2. The electrode 53 is connected to the first terminal T1 via a via V11. A path extending from the antenna terminal TA to the first terminal T1 through the via V12, the electrodes 51, 52, and 53, and the via V11 corresponds to the series arm circuit in the filter FLT1 in FIG. 2.

As illustrated in FIG. 5, the electrode 52 is connected to an electrode pad P7 disposed on the upper surface of the dielectric substrate 20 via a via V10. An electrode pad P8 is disposed at a position apart from the electrode pad P7 in the X-axis direction. Between the electrode pads P7 and P8, the inductor L11 that is a chip component is connected. The electrode pad P8 is connected to an electrode 58 via a via V17. The electrode 58 faces the ground electrode GND1 to be spaced apart from it. The electrode 58 and the ground electrode GND1 form the capacitor C13 in FIG. 2.

An electrode 57 is also connected to the via V17 that connects the electrode pad P8 and the electrode 58. An electrode 56 is disposed apart from the electrode 57 in the upper-surface direction (the positive direction of the Z axis). The electrodes 56 and 57 form the capacitor C14. The electrode 56 is connected to the switching circuit SWIC disposed on the upper surface of the dielectric substrate 20 via a via V4. In the switching circuit SWIC, the switch SW11 (FIG. 2) is formed between a via V1 and the via V4 that are connected to the ground electrode GND1. A path extending from the electrode 52 to the ground electrode GND1 through the inductor L11 and the electrode 58 and a path extending from the electrode 52 to the ground electrode GND1 through the inductor L11, the electrodes 57 and 56, and the switching circuit SWIC correspond to the parallel arm circuit in the filter FLT1 in FIG. 2.

Next, the configuration of the low-pass filter FLT2 will be described. On the upper surface of the dielectric substrate 20, electrode pads P2, P3, P5, and P6 are spaced apart from each other in the order of increasing the distance from the electrode pad P1 connected to the antenna terminal TA in the positive direction of the X axis. Between the electrode pads P1 and P2, the inductor L21 that is a chip component is connected.

The electrode pads P2 and P3 are electrically connected via a wiring pattern 60 formed in the dielectric substrate 20. The electrode pad P3 is connected to the electrode pad P5 via a wiring pattern 61 formed in the dielectric substrate 20. Between the electrode pads P5 and P6, the inductor L22 that is a chip component is connected. The electrode pad P6 is connected to the second terminal T2 via a via V13. A path extending from the antenna terminal TA to the second terminal T2 through the via V12, the inductor L21, the wiring patterns 60 and 61, the inductor L22, and the via V13 corresponds to the series arm circuit in the filter FLT2 in FIG. 2.

An electrode pad P4 is disposed at a position apart from the electrode pad P3 in the negative direction of the Y axis. Between the electrode pads P3 and P4, the inductor L23 that is a chip component is connected. The electrode pad P4 is connected to an electrode 59 via a via V14. The electrode 59 faces the ground electrode GND1 to be spaced apart from it. The electrode 59 and the ground electrode GND1 form the capacitor C21 in FIG. 2.

An electrode 55 is also connected to the via V14 that connects the electrode pad P4 and the electrode 59. An electrode 54 is disposed apart from the electrode 55 in the upper-surface direction (the positive direction of the Z axis). The electrodes 54 and 55 form the capacitor C22 in FIG. 2. The electrode 55 is connected to the switching circuit SWIC via a via V3. In the switching circuit SWIC, the switch SW21 (FIG. 2) is formed between the vias V3 and V6 that are connected to the ground electrode GND1. A path extending from the electrode pad P3 to the ground electrode GND1 through the inductor L23 and the electrode 59 and a path extending from the electrode pad P3 to the ground electrode GND1 through the inductor L23, the electrodes 54 and 55, and the switching circuit SWIC correspond to the parallel arm circuit in the filter FLT2 in FIG. 2.

The switching circuit SWIC is disposed on the dielectric substrate 20 via the vias V1 to V9. As described above, the switch SW11 is formed between the vias V1 and V4, and the switch SW21 is formed between the vias V3 and V6 in the switching circuit SWIC. That is, a radio frequency region RF-AR, which is a broken-line region including the vias V1 to V6, is a radio frequency region in which a radio-frequency signal passes.

On the other hand, a control region DC-AR, which is a broken-line region including the vias V7 to V9, is a region in which a control circuit (not illustrated) for controlling the switches SW11 and SW21 in the switching circuit SWIC is formed. The via V9 is connected to the power terminal PWR via a wiring pattern 63 and a via V16. The via V7 is connected to the control terminal CTL via a wiring pattern 62 and a via V15.

In the multiplexer 100 according to the first embodiment, the series arm circuits and the parallel arm circuits in the filters FLT1 and FLT2 correspond to the radio-frequency line RF in FIG. 3. A path extending from the power terminal PWR and the control terminal CTL to the switching circuit SWIC corresponds to the control line DC in FIG. 3.

As is apparent from FIGS. 4 and 6, the respective elements are disposed and formed such that the radio-frequency line RF and the control line DC do not overlap when the dielectric substrate 20 is viewed in plan in the multiplexer 100. Accordingly, the electromagnetic coupling between the radio-frequency line RF and the control line DC is suppressed. A radio-frequency component is therefore unlikely to be superimposed on a signal passing through the control line DC. This leads to the suppression of the generation of a harmonic in a nonlinear element (the switching circuit SWIC). As a result, the generation of an unnecessary wave in the radio-frequency line RF can be suppressed.

In general, some continuity resistance is present even in a conductive state in a switch formed in the switching circuit SWIC. For the reduction in the passing loss of a radio-frequency signal in tunable filters like the filters FLT1 and FLT2 included in the multiplexer 100, it is desired that a switch for impedance switching not be disposed on the side of the series arm circuit, which is a main path through which a radio-frequency signal passes, but on the side of the parallel arm circuit. Even in the case where a switch is disposed on the side of the parallel arm circuit, it is desired that the continuity resistance of the switch be as low as possible.

For the reduction in the continuity resistance of a switch in the switching circuit SWIC, the area of the radio frequency region RF-AR in the switching circuit SWIC needs to be increased. However, since the size of the switching circuit SWIC is limited, the area of the control region DC-AR has to be reduced when the area of the radio frequency region RF-AR is increased. If the area of the control region DC-AR becomes small, the influence of nonlinearity becomes large. This leads to the increase in the degree of distortion of a signal passing through the control line. As a result, an unnecessary wave is easily generated in the radio-frequency line.

By disposing the respective elements such that a radio-frequency line and a control line do not overlap when a dielectric substrate at which tunable filters are formed is viewed in plan for the suppression of the electromagnetic coupling between the radio-frequency line and the control line like in the first embodiment, the generation of an unnecessary wave in the radio-frequency line can be suppressed even in the case where the control region DC-AR is small while the continuity resistance of a switch can be reduced by increasing in size the radio frequency region RF-AR.

### Design Considerations

It is desired not to couple the control line DC to the capacitors forming the series arm circuit in the high-pass filter FLT1 among other components on the radio-frequency line. As described above, the harmonic generated by a nonlinear element causes the generation of an unnecessary wave in the radio-frequency line. The frequency (2f0) of a harmonic is higher than the fundamental frequency (f0) of an original radio-frequency signal. Accordingly, when a harmonic is coupled to the series arm circuit in the high-pass filter, the frequency of the harmonic becomes the pass band of the filter, and the harmonic is outputted after passing through the filter (FIGS. 7A and 7B). That is, the high-pass filter is susceptible to a harmonic.

On the other hand, when a harmonic is coupled to the series arm circuit in the low-pass filter, the frequency of the harmonic becomes the attenuation band of the filter as illustrated in FIGS. 8A and 8B. Accordingly, the coupled harmonic is unlikely to pass through the filter. That is, the low-pass filter is less susceptible to a harmonic than the high-pass filter.

Accordingly, in the arrangement of elements at the dielectric substrate, it is important that the coupling between the control line and the series arm circuit in the high-pass filter be prevented as much as possible.

### Second Embodiment

In the multiplexer 100 according to the first embodiment described above, the radio-frequency line and the control line do not overlap in the lamination direction of the substrate. However, in the case where an existing product is improved and the arrangement of electrodes at a substrate at which a multiplexer is to be disposed is determined in advance, a radio-frequency line and a control line may overlap even if the arrangement of elements in the multiplexer is carefully considered.

In the second embodiment, the configuration will be described in which a ground electrode is formed at a layer between elements forming a radio-frequency line and elements forming a control line for the suppression of coupling between the radio-frequency line and the control line in the case where the overlap between the radio-frequency line and the control line cannot be avoided.

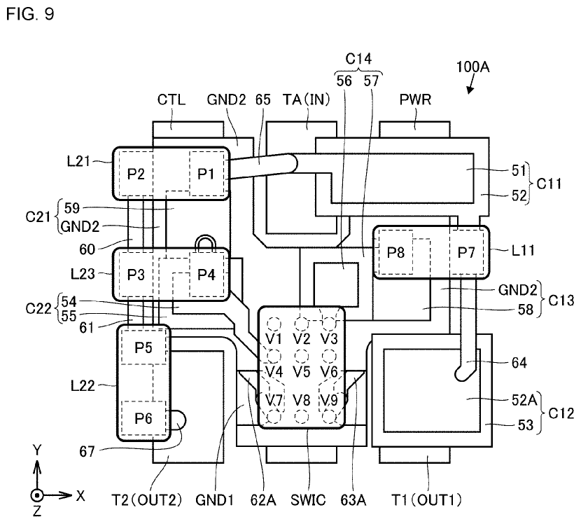

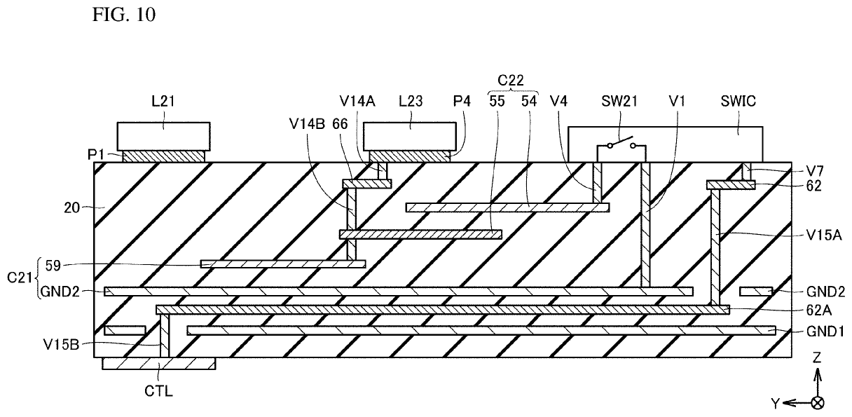

The configuration of a multiplexer 100A to which a filter device according to the second embodiment is applied will be described with reference to FIGS. 9 and 10. FIG. 9 is a plan view of the multiplexer 100A. FIG. 10 is a schematic cross-sectional view of the multiplexer in FIG. 9 along a control wiring line connecting the switching circuit SWIC and the control terminal CTL. In the plan view in FIG. 9, like in FIG. 4, a dielectric portion is not illustrated and internal elements such as wiring patterns are illustrated in the state where they are visible in the dielectric substrate 20. For the sake of convenience, a negative direction of the Z axis will be referred to as an undersurface side of the dielectric substrate 20, and the positive direction of the Z axis will be referred to as an upper surface side of the dielectric substrate 20.

Referring to FIGS. 9 and 10, the arrangement of terminal electrodes on the undermost surface in the multiplexer 100A differs from that in the multiplexer 100 according to the first embodiment. Specifically, the control terminal CTL is disposed in the top-left corner, and the power terminal PWR is disposed in the top-right corner in FIG. 9. Between the control terminal CTL and the power terminal PWR, the antenna terminal TA that is an input terminal is disposed. The first terminal T1 that is the output terminal of the filter FLT1 is disposed in the bottom-right corner, and the second terminal T2 that is the output terminal of the filter FLT2 is disposed in the bottom-left corner in FIG. 9.

In the multiplexer 100A, the ground electrode GND1 is formed in a large area at a layer spaced apart from the terminal electrodes in the upper-surface direction (in the positive direction of the Z axis), and a ground electrode GND2 is formed at a layer spaced apart from the ground electrode GND1 in the upper-surface direction as illustrated in FIG. 10.

First, the configuration of the high-pass filter FLT1 will be described. The antenna terminal TA is connected to the electrode 51 extending in the positive direction of the X axis and a wiring pattern 65 extending in the negative direction of the X axis via a via (not illustrated). The electrode 52 is disposed apart from the electrode 51 on the undersurface side of the electrode 51 (in the negative direction of the Z axis). The electrodes 51 and 52 form the capacitor C11.

The electrode 52 is connected to an electrode 52A that is spaced apart from the electrode 52 in the negative direction of the Y axis and is disposed in the upper-surface direction of the first terminal T1 (the positive direction of the Z axis) via a wiring pattern 64. The electrode 53 is disposed at a layer between the electrode 52A and the first terminal T1 to face the electrode 52A. The electrodes 52A and 53 form the capacitor C12. The electrode 53 is connected to the first terminal T1 via a via (not illustrated). A path extending from the antenna terminal TA to the first terminal T1 via the electrodes 51 and 52, the wiring pattern 64, and the electrodes 52A and 53 corresponds to the series arm circuit in the filter FLT1.

The wiring pattern 64 is connected to the electrode pad P7 disposed on the upper surface of the dielectric substrate 20 via a via (not illustrated). The electrode pad P7 is disposed between the electrodes 52 and 52A in the Y-axis direction when the dielectric substrate 20 is viewed in plan.

The electrode pad P8 is disposed at a position spaced apart from the electrode pad P7 in the negative direction of the X axis. Between the electrode pads P7 and P8, the inductor L11 that is a chip conductor is connected.

The electrode pad P8 is connected to the electrodes 57 and 58 disposed between the electrode pad P8 and the ground electrode GND2 via a via (not illustrated). The electrode 57 is offset from the electrode 58 in the negative direction of the X axis when the dielectric substrate 20 is viewed in plan and does not practically face the electrode 58 in the lamination direction (the Z-axis direction).

The electrode 58 faces the ground electrode GND2. The electrode 58 and the ground electrode GND2 form the capacitor C13. The electrode 56 is disposed apart from the electrode 57 in the upper-surface direction (the positive direction of the Z axis). The electrodes 56 and 57 form the capacitor C14. The electrode 56 is connected to the switching circuit SWIC disposed on the upper surface of the dielectric substrate 20 via the via V3.

In the switching circuit SWIC, the switch SW11 is formed between the vias V6 and V3 that are connected to the ground electrode GND2. A path extending from the wiring pattern 64 to the ground electrode GND2 through the inductor L11 and the electrode 58 and a path extending from the wiring pattern 64 to the ground electrode GND1 through the inductor L11, the electrodes 57 and 56, and the switching circuit SWIC correspond to the parallel arm circuit in the filter FLT1 in FIG. 2.

Next, the configuration of the low-pass filter FLT2 will be described. The wiring pattern 65 is connected to the electrode pad P1 disposed on the upper surface of the dielectric substrate 20 via a via (not illustrated). The electrode pad P1 is disposed above the control terminal CTL when the dielectric substrate 20 is viewed in plan.

On the upper surface of the dielectric substrate 20, the electrode pad P2 is disposed at a position spaced apart from the electrode pad P1 in the negative direction of the X axis. Between the electrode pads P1 and P2, the inductor L21 that is a chip component is connected. On the upper surface of the dielectric substrate 20, the electrode pads P3, P5, and P6 are spaced apart from each other in the order of increasing the distance from the electrode pad P2 in the negative direction of the Y axis.

The electrode pads P2 and P3 are electrically connected via the wiring pattern 60 formed in the dielectric substrate 20. The electrode pad P3 is connected to the electrode pad P5 via the wiring pattern 61 formed in the dielectric substrate 20. Between the electrode pads P5 and P6, the inductor L22 that is a chip component is connected. The electrode pad P6 is connected to the second terminal T2 via a wiring pattern 67 and a via (not illustrated). A path extending from the antenna terminal TA to the second terminal T2 through the inductor L21, the wiring patterns 60 and 61, the inductor L22, and a wiring pattern 67 corresponds to the series arm circuit in the filter FLT2.

The electrode pad P4 is disposed at a position spaced apart from the electrode pad P3 in the positive direction of the X axis. Between the electrode pads P3 and P4, the inductor L23 that is a chip component is connected.

As illustrated in FIG. 10, the electrode pad P4 is connected to the electrode 59 via a via V14A, the wiring pattern 66, and a via V14B. The electrode 59 faces the ground electrode GND2 to be spaced apart from it. The electrode 59 and the ground electrode GND2 form the capacitor C21. The electrode 55 is also connected to the via V14B that connects the wiring pattern 66 and the electrode 59. The electrode 54 is disposed apart from the electrode 55 in the upper-surface direction (the positive direction of the Z axis). The electrodes 54 and 55 form the capacitor C22.

The electrode 54 is connected to the switching circuit SWIC via the via V4. In the switching circuit SWIC, the switch SW21 is formed between the vias V1 and V4 that are connected to the ground electrode GND2. A path extending from the electrode pad P3 to the ground electrode GND2 through the inductor L23 and the electrode 59 and a path extending from the electrode pad P3 to the ground electrode GND2 through the inductor L23, the electrodes 54 and 55, and the switching circuit SWIC correspond to the parallel arm circuit in the filter FLT2.

The switching circuit SWIC is disposed between the first terminal T1 and the second terminal T2 in the X-axis direction when the dielectric substrate 20 is viewed in plan. As described above, the power terminal PWR for receiving driving power for the switching circuit SWIC and the control terminal CTL for receiving a control signal for the switching circuit SWIC are disposed at corners in an end portion in the positive direction of the Y axis with respect to the switching circuit SWIC. Accordingly, when the dielectric substrate 20 is viewed in plan, a wiring path extending from the power terminal PWR and the control terminal CTL to the switching circuit SWIC partly overlaps the radio-frequency line in the filter FLT2 even if any path is selected as the wiring path.

In the second embodiment, at least a part of the control line extending from the control terminal CTL to the switching circuit SWIC which faces the radio-frequency line is formed at the layer between the ground electrodes GND1 and GND2 as illustrated in FIG. 10.

More specifically, the control terminal CTL is connected to a wiring pattern 62A formed at the layer between the ground electrodes GND1 and GND2 via a via V15B. The wiring pattern 62A extending from a position around the control terminal CTL to a position below the switching circuit SWIC. A via V15A penetrates the ground electrode GND2 and connects the wiring pattern 62 formed above the wiring pattern 62A (the positive direction of the Z axis) and the wiring pattern 62A. The wiring pattern 62 is connected to the switching circuit SWIC via the via V7.

At least a part of the wiring path extending from the power terminal PWR to the switching circuit SWIC which overlaps the filter FLT1 when viewed in plan is similarly formed at the layer between the ground electrodes GND1 and GND2.

Thus, in the multiplexer 100A according to the second embodiment, the ground electrode GND2 is formed between the radio-frequency line and the control line. A part of the control line which overlaps the radio-frequency line when viewed in plan is shielded by the ground electrode GND2. Accordingly, the electromagnetic coupling between the radio-frequency line and the control line can be suppressed even though the radio-frequency line and the control line overlap when the dielectric substrate 20 is viewed in plan. The occurrence of a harmonic in the nonlinear element (in the switching circuit SWIC) is therefore suppressed. This can lead to the suppression of the occurrence of an unnecessary wave in the radio-frequency line RF.

In the series arm circuits in the filters FLT1 and FLT2, it is desired that the wiring patterns 60, 61, and 64 formed in the dielectric substrate 20 not overlap the ground electrodes GND1 and GND2 when the dielectric substrate 20 is viewed in plan. Since the ground electrode GND2 is formed at a layer nearer to the upper surface of the dielectric substrate 20 than a layer at which the ground electrode GND1 is formed in the second embodiment, the parasitic capacitances between the wiring patterns 60, 61, and 64 formed in the dielectric substrate 20 and the ground electrode GND2 are increased and may have an influence upon the impedance of the series arm circuits. Since a main radio-frequency signal passes through the series arm circuit, the passing loss of the filter may increase when the impedance of the series arm circuit deviates from characteristic impedance (e.g., 50Ω). Accordingly, by disposing the wiring patterns 60, 61, and 64 and the ground electrodes GND1 and GND2 such that the wiring patterns 60, 61, and 64 do not overlap the ground electrodes GND1 and GND2, the impedance change made by the parasitic capacitance can be suppressed and the degradation of the filter characteristics due to the loss increase can be suppressed.

Although the case has been described in the first and second embodiments where a multiplexer is a duplexer including two filters, the multiplexer may be a filter including three or more filters. Alternatively, the multiplexer may be a filter device including a single filter.

### Third Embodiment

The multiplexer in which a filter is formed of an inductor and a capacitor has been described in the first and second embodiments.

In the third embodiment, a multiplexer including, as tunable filters, surface acoustic wave (SAW) filters each including SAW resonators will be described.

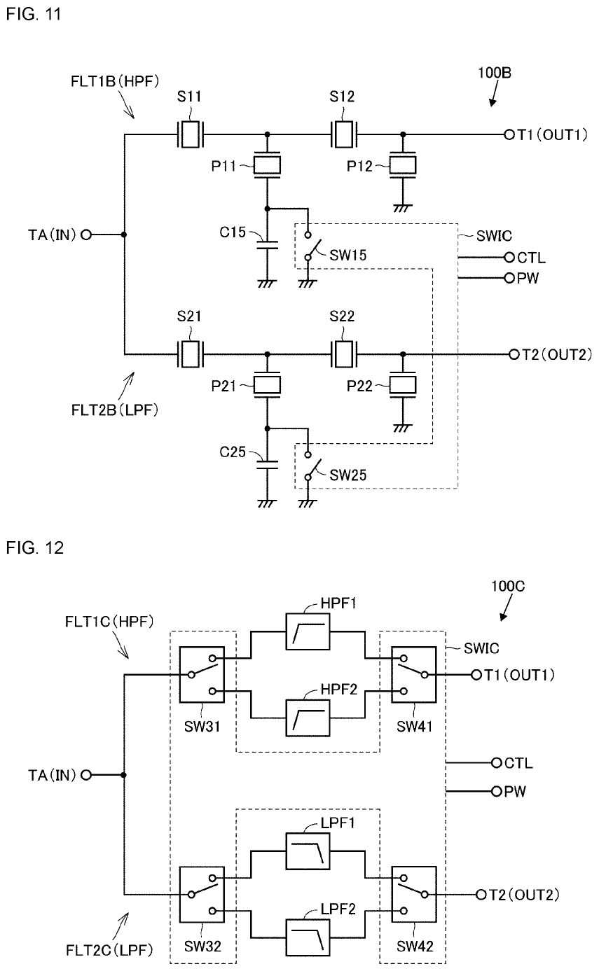

FIG. 11 is a circuit diagram of a multiplexer 100B to which a filter device according to the third embodiment is applied. Referring to FIG. 11, the multiplexer 100B includes filters FLT1B and FLT2B that are connected to the antenna terminal TA.

The filter FLT1B is connected between the antenna terminal TA and the first terminal T1. The filter FLT1B functions as a high-pass filter (HPF) that has a frequency range in the high band group as a pass band and a frequency range in the low band group as an attenuation band. The filter FLT1B includes series arm resonators S11 and S12 forming a series arm circuit, parallel arm resonators P11 and P12, a capacitor C15, and a switch SW15 forming a parallel arm circuit. Each of the series arm resonators S11 and S12 and the parallel arm resonators P11 and P12 is formed of a SAW resonator in which an interdigital transducer (IDT) electrode is formed on a piezoelectric substrate.

The series arm resonators S11 and S12 are connected in series between the antenna terminal TA and the first terminal T1. One end of the parallel arm resonator P11 is connected to a connection node between the series arm resonators S11 and S12. The capacitor C15 is connected between the other end of the parallel arm resonator P11 and the ground potential. The switch SW15 is connected in parallel with the capacitor C15. The parallel arm resonator P12 is connected between the first terminal T1 and the ground potential.

The filter FLT2B is connected between the antenna terminal TA and the second terminal T2. The filter FLT2B functions as a low-pass filter (LPF) that has a frequency range in the low band group as a pass band and a frequency range in the high band group as an attenuation band. The filter FLT2B includes series arm resonators S21 and S22 forming a series arm circuit, parallel arm resonators P21 and P22, a capacitor C25, and a switch SW25 forming a parallel arm circuit. Each of the series arm resonators S21 and S22 and the parallel arm resonators P21 and P22 is also formed of a SAW resonator.

The series arm resonators S21 and S22 are connected in series between the antenna terminal TA and the second terminal T2. One end of the parallel arm resonator P21 is connected to a connection node between the series arm resonators S21 and S22. The capacitor C25 is connected between the other end of the parallel arm resonator P21 and the ground potential. The switch SW25 is connected in parallel with the capacitor C25. The parallel arm resonator P22 is connected between the second terminal T2 and the ground potential.

In the filters FLT1B and FLT2B, the resonant frequencies of the parallel arm circuits can be changed and the frequencies at attenuation poles formed by the parallel arm circuits can be adjusted by causing the switches SW15 and SW25 to perform switching.

Each of the switch SW15 in the filter FLT1B and the switch SW25 in the filter FLT2B is, for example, a transistor and is formed in the switching circuit SWIC. Driving power is supplied to the switching circuit SWIC via the power terminal PWR. A control signal for operating the switches SW15 and SW25 is transmitted to the switching circuit SWIC from an external control device (not illustrated) via the control terminal CTL.

Since such a multiplexer including tunable filters formed of SAW resonators also includes a nonlinear element in the control circuit in the switching circuit SWIC, an unnecessary wave is generated when a radio-frequency signal passes through the nonlinear element and may lead to the degradation of the filter characteristics.

Accordingly, in the multiplexer 100B, the radio-frequency line that passes a radio-frequency signal and the control line that transmits driving power or a control signal for the switching circuit SWIC are arranged so as not to overlap each other when an insulating substrate (insulator) at which the multiplexer 100B is formed is viewed in plan. More specifically, the IDT electrode included in the SAW resonator and the control line are arranged so as not to overlap each other. In the case of this arrangement, the electromagnetic coupling between the radio-frequency line and the control line is suppressed and the generation of an unnecessary wave is suppressed in the radio-frequency line. This can lead to the suppression of the degradation of the filter characteristics.

### Fourth Embodiment

The configurations of the tunable filters in the multiplexers according to the first to third embodiments have been described in which a frequency at the specific attenuation pole of a parallel arm circuit is changed by causing a switch to perform switching.

In a multiplexer according to the fourth embodiment, the configuration will be described in which a switch in a tunable filter switches between a plurality of filters.

FIG. 12 is a circuit diagram of a multiplexer 100C to which a filter device according to the fourth embodiment is applied. Referring to FIG. 12, the multiplexer 100C includes filters FLT1C and FLT2C that are connected to the antenna terminal TA.

The filter FLT1C is connected between the antenna terminal TA and the first terminal T1. The filter FLT1C functions as a high-pass filter (HPF) that has a frequency range in the high band group as a pass band and a frequency range in the low band group as an attenuation band. The FLT1C includes switches SW31 and SW41 and high-pass filters HPF1 and HPF2 having different bandpass characteristics.

The antenna terminal TA is connected to a common terminal 311 of the switch SW31. A selection terminal 312 of the switch SW31 is connected to the high-pass filter HPF1. A selection terminal 313 of the switch SW31 is connected to the high-pass filter HPF2. A common terminal 411 of the switch SW41 is connected to the first terminal T1. Selection terminals 412 and 413 of the switch SW41 are connected to the high-pass filters HPF1 and HPF2, respectively.

The switches SW31 and SW41 are formed in the switching circuit SWIC and operate in accordance with a control signal transmitted from an external control device (not illustrated). When the high-pass filter HPF1 is used, the selection terminal 312 of the switch SW31 is selected and the selection terminal 412 of the switch SW41 is selected. On the other hand, when the high-pass filter HPF2 is used, the selection terminal 313 of the switch SW31 is selected and the selection terminal 413 of the switch SW41 is selected.

The filter FLT2C is connected between the antenna terminal TA and the second terminal T2. The filter FLT2C functions as a low-pass filter (LPF) that has a frequency range in the low band group as a pass band and a frequency range in the high band group as an attenuation band. The filter FLT2C includes switches SW32 and SW42 and low-pass filters LPF1 and LPF2 having different bandpass characteristics.

The antenna terminal TA is connected to a common terminal 321 of the switch SW32. A selection terminal 322 of the switch SW32 is connected to the low-pass filter LPF1. A selection terminal 323 of the switch SW32 is connected to the low-pass filter LPF2. A common terminal 421 of the switch SW42 is connected to the second terminal T2. Selection terminals 422 and 423 of the switch SW42 are connected to the low-pass filters LPF1 and LPF2, respectively.

The switches SW32 and SW42 are formed in the switching circuit SWIC and operate in accordance with a control signal transmitted from an external control device (not illustrated). When the low-pass filter LPF1 is used, the selection terminal 322 of the switch SW32 is selected and the selection terminal 422 of the switch SW42 is selected. On the other hand, when the low-pass filter LPF2 is used, the selection terminal 323 of the switch SW32 is selected and the selection terminal 423 of the switch SW42 is selected.

Each of the high-pass filters HPF1 and HPF2 and the low-pass filters LPF1 and LPF2 may be an LC filter according to the first embodiment or a SAW filter according to the third embodiment.

Thus, also in the multiplexer 100C in which a switch in a tunable filter switches between a plurality of filters, a radio-frequency line that passes a radio-frequency signal and a control line that transmits driving power or a control signal for the switching circuit SWIC are arranged so as not to overlap each other when an insulating substrate (insulator) at which the multiplexer 100C is formed is viewed in plan. As a result, the generation of an unnecessary wave in the radio-frequency line can be suppressed and the degradation of the filter characteristics can be suppressed.

In the multiplexer 100C exemplarily illustrated in FIG. 12, each of the filters FLT1C and FLT2C includes two different filters, but may include three or more filters.

The embodiments disclosed herein are illustrative only and are not intended to be limiting in any way. The scope of the present disclosure is defined by the appended claims rather than the foregoing description of the embodiments, and it should be understood that all the changes conceived from the meaning and scope of the claims and their equivalents are included in the scope of the present disclosure.
1 communication apparatus
10 radio-frequency front-end circuit
15 RFIC
20 dielectric substrate
51 to 59 and 52A electrode
60 to 67 and 62A wiring pattern
100 and 100A to 100C multiplexer
110, 120, SW11, SW15, SW21, SW25, SW31, SW32, SW41, and SW42 switch
111 to 114, 121 to 123, 311 to 313, 321 to 323, 411 to 413, 421 to 423, CTL, PWR, T1, T2, and TA terminal
132 to 134, 142, and 143 band-pass filter
150 and 160 amplification circuit
152, 154, 162, and 163 amplifier
200 nonlinear element
ANT antenna device
C11 to C14, C21, and C22 capacitor
DC control line
FLT1, FLT1B, FLT1C, FLT2, FLT2B, and FLT2C filter
GND1 and GND2 ground electrode
HPF1 and HPF2 high-pass filter
LPF1 and LPF2 low-pass filter
L11 and L21 to L23 inductor
P1 to P8 electrode pad
PWR power terminal
RF radio-frequency line
SWIC switching circuit
V1 to V17, V14A, V14B, V15A, and V15B via

1. A filter device comprising:
a flat-shaped insulator;
a first filter disposed in the insulator and configured to pass a radio-frequency signal in a first frequency band; and
a switching circuit disposed on the insulator and configured to change at least one of a pass band and an attenuation band of the first filter,
wherein a control line configured to supply driving power or a control signal to the switching circuit is provided at the insulator, and
wherein the control line is disposed so as not to overlap a radio-frequency line passing a radio-frequency signal in the first filter when the insulator is viewed in plan.

2. The filter device according to claim 1, wherein the insulator is a dielectric substrate having a multilayer structure.

3. The filter device according to claim 1,
wherein the first filter includes a first series arm circuit and a first parallel arm circuit, the first series arm circuit being provided between an antenna terminal and a first terminal, and the first parallel arm circuit being connected between the first series arm circuit and a ground potential, and
wherein the switching circuit is configured to change a resonant frequency of the first parallel arm circuit.

4. The filter device according to claim 1, further comprising a second filter provided at the insulator and configured to pass a radio-frequency signal in a second frequency band different from the first frequency band,
wherein the control line is disposed so as not to overlap a radio-frequency line in the second filter when the insulator is viewed in plan.

5. The filter device according to claim 4, wherein the switching circuit is configured to change at least one of a pass band and an attenuation band of the second filter.

6. A filter device comprising:
a dielectric substrate having a multilayer structure;
a first filter disposed at the dielectric substrate and configured to pass a radio-frequency signal in a first frequency band; and
a switching circuit disposed at the dielectric substrate and configured to change at least one of a pass band and an attenuation band of the first filter,
wherein a control line configured to supply driving power or a control signal to the switching circuit is provided at the dielectric substrate,
wherein the control line overlaps at least a part of a radio-frequency line passing a radio-frequency signal in the first filter when the dielectric substrate is viewed in plan, and
wherein, in a portion in which the control line and the radio-frequency line overlap, a ground electrode is disposed between the control line and the radio-frequency line.

7. The filter device according to claim 6,
wherein the first filter includes a first series arm circuit and a first parallel arm, the first series arm circuit being provided between an antenna terminal and a first terminal, and the first parallel arm circuit being connected between the first series arm circuit and a ground potential, and
wherein the control line does not overlap the first series arm circuit when the dielectric substrate is viewed in plan.

8. The filter device according to claim 7,
wherein the first series arm circuit includes a capacitor, and
wherein the control line does not overlap the capacitor when the dielectric substrate is viewed in plan.

9. The filter device according to claim 7, wherein the first series arm circuit and the ground electrode do not overlap when the dielectric substrate is viewed in plan.

10. The filter device according to claim 7,
wherein the control line overlaps a part of the first parallel arm circuit when the dielectric substrate is viewed in plan, and
wherein, in a portion in which the control line and the first parallel arm circuit overlap, the ground electrode is disposed between the control line and the first parallel arm circuit.

11. The filter device according to claim 6, further comprising a second filter provided at the dielectric substrate and configured to pass a radio-frequency signal in a second frequency band different from the first frequency band.

12. The filter device according to claim 11, wherein the switching circuit is configured to change at least one of a pass band and an attenuation band of the second filter.

13. The filter device according to claim 1,
wherein the switching circuit includes a radio frequency region where a radio-frequency signal passes and a control region where driving power or a control signal passes, and
wherein, in the switching circuit, an area of the radio frequency region is larger than an area of the control region.

14. A filter device comprising:
a dielectric substrate;
a first filter disposed at the dielectric substrate and configured to pass a radio-frequency signal in a first frequency band;
a second filter provided at the dielectric substrate and configured to pass a radio-frequency signal in a second frequency band different from the first frequency band; and
a switching circuit disposed at the dielectric substrate and configured to switch between the first filter and the second filter,
wherein a control line configured to supply driving power or a control signal to the switching circuit is provided at the dielectric substrate, and
wherein the control line is disposed so as not to overlap a radio-frequency line passing a radio-frequency signal in each of the first filter and the second filter when the dielectric substrate is viewed in plan.

15. A radio-frequency front-end circuit comprising:
the filter device according to claim 1; and
an amplification circuit connected to the filter device.

16. A communication apparatus comprising:
the radio-frequency front-end circuit according to claim 15; and
an RF signal processing circuit connected to the radio-frequency front-end circuit.

17. The filter device according to claim 2,
wherein the first filter includes a first series arm circuit and a first parallel arm circuit, the first series arm circuit being provided between an antenna terminal and a first terminal, and the first parallel arm circuit being connected between the first series arm circuit and a ground potential, and
wherein the switching circuit is configured to change a resonant frequency of the first parallel arm circuit.

18. The filter device according to claim 2, further comprising a second filter provided at the insulator and configured to pass a radio-frequency signal in a second frequency band different from the first frequency band,
wherein the control line is disposed so as not to overlap a radio-frequency line in the second filter when the insulator is viewed in plan.

19. The filter device according to claim 3, further comprising a second filter provided at the insulator and configured to pass a radio-frequency signal in a second frequency band different from the first frequency band,
wherein the control line is disposed so as not to overlap a radio-frequency line in the second filter when the insulator is viewed in plan.

20. The filter device according to claim 8, wherein the first series arm circuit and the ground electrode do not overlap when the dielectric substrate is viewed in plan.
